(19) United States
(12) Patent Application Publication
(10) Pub. No.: US 2012/0250233 A1
(43) Pub. Date: Oct. 4, 2012

(54) ELECTRONIC DEVICE WITH SUPPORTING APPARATUS

(75) Inventors: GUANG-YAO LEE, Tu-Cheng (TW); YI-SHENG LIN, Tu-Cheng (TW); BIN LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/211,275

(22) Filed: Aug. 16, 2011

(30) Foreign Application Priority Data
Apr. 2, 2011 (CN) 201110083105.4

(51) Int. Cl. H05K 7/00; F16M 13/00

(52) U.S. Cl. 361/679.01; 248/201

(57) ABSTRACT

A support for an electronic device includes a main body, a mounting apparatus, and a supporting apparatus. The mounting apparatus includes a fixing bracket mounted to the main body, an installing bracket fixed to the fixing bracket, and an engaging member slidably mounted between the fixing bracket and the installing bracket. The supporting apparatus includes a connecting bracket detachably mounted to the fixing bracket, and a supporting bracket connected the connecting bracket. A connecting piece extends from the connecting bracket and defines a connecting hole therein. The engaging member includes a first hook inserted into the connecting hole, the supporting apparatus is fixed to the mounting apparatus.

### CROSS-REFERENCE OF RELATED APPLICATION

Relevant subject matter is disclosed in a pending U.S. patent application, titled “ELECTRONIC DEVICE WITH SUPPORTING APPARATUS”, with the application Ser. No. 13/198,730, filed on Aug. 5, 2011, which is assigned to the same assignee as this patent application.

### BACKGROUND

1. Technical Field

The present disclosure relates to electronic devices, and particularly, to an electronic device having a supporting apparatus.

2. Description of Related Art

An electronic device, such as an all-in-one computer or a liquid crystal display, is often secured to a supporting mechanism by a plurality of fasteners or screws. However, it is time-consuming and often difficult to disassemble the supporting mechanism from the electronic device when the electronic device needs to be hung on a wall.

### BRIEF DESCRIPTION OF THE DRAWINGS

The components of the drawings are not necessarily drawn to scale, the emphasis instead being placed upon clearly illustrating the principles of the embodiments. Moreover, in the drawings, like reference numerals designate corresponding parts throughout several views.

FIG. 1 is an exploded, isometric view of an exemplary embodiment of an electronic device, the electronic device includes a mounting apparatus and a supporting apparatus.

FIG. 2 is an exploded, isometric view of the mounting apparatus of FIG. 1.

FIG. 3 is similar to FIG. 2, but viewed from another perspective.

FIG. 4 is a partly assembled, isometric view of FIG. 3.

FIG. 5 is an exploded, isometric view of the supporting apparatus of FIG. 1.

FIG. 6 is an assembled, isometric view of the supporting apparatus of FIG. 5.

FIGS. 7-9 are isometric, cutaway views showing the process of assembling the electronic device of FIG. 1.

FIG. 10 is an assembled, isometric view of the electronic device of FIG. 1.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

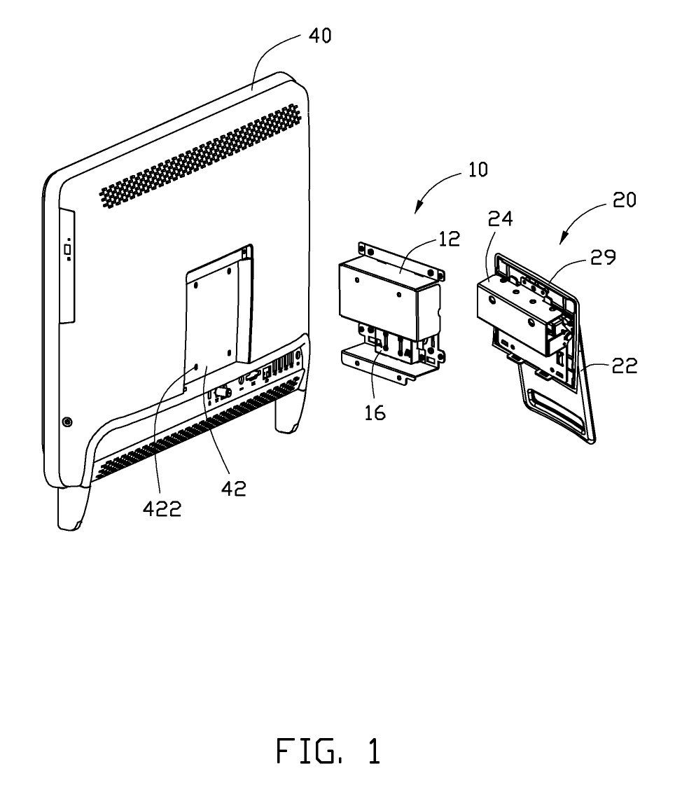

Referring to FIG. 1, an embodiment of an electronic device includes a main body 40, a mounting apparatus 10 fixed to the main body 40, and a supporting apparatus 20 detachably latched to the mounting apparatus 10. A rectangular recess 42 is defined in a rear side of the main body 40, with a bottom surface thereof extending through a bottom surface of the main body 40. Four screw holes 422 are defined in the base of the recess 42. In the embodiment, the main body 40 is part of an all-in-one computer.

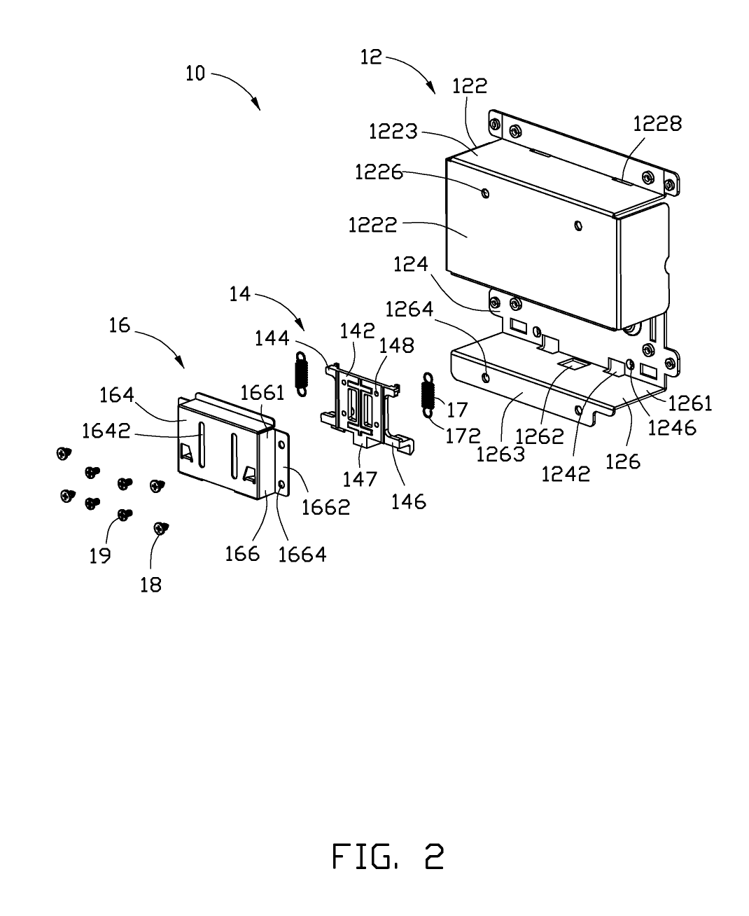

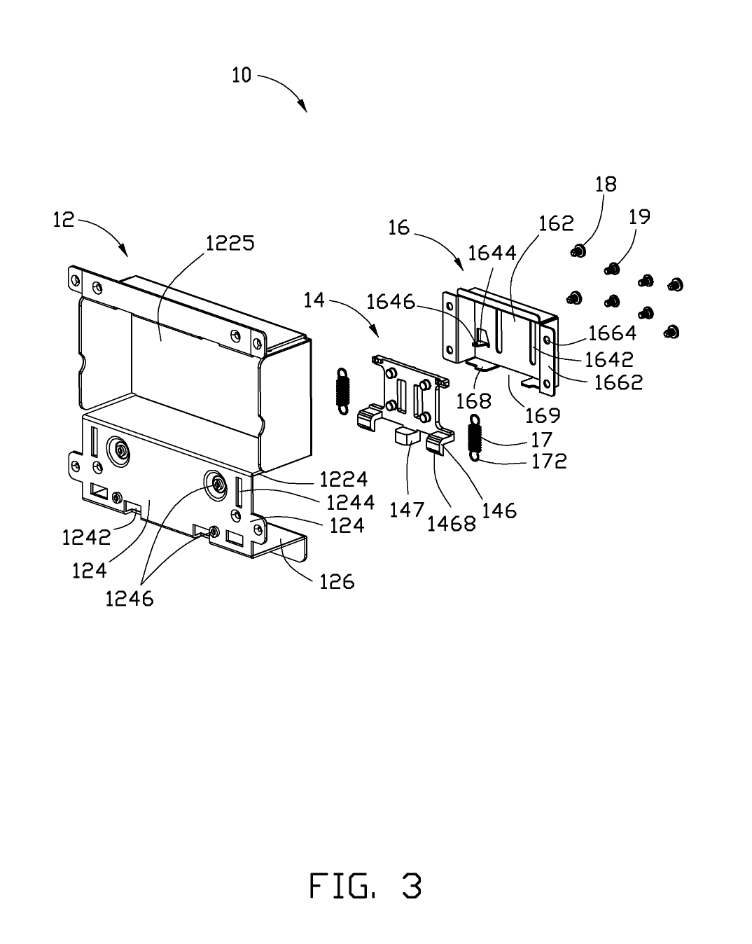

Referring to FIG. 2 and FIG. 3, the mounting apparatus 10 includes a fixing bracket 12, an engaging member 14, an installing bracket 16, two resilient members 17, four first screws 18, and four second screws 19.

The fixing bracket 12 includes a frame 122 with a rectangular box-shape. The frame 122 defines an opening in the rear side. The frame 122 includes a rectangular front wall 1222 opposite to the opening, a top wall 1223 perpendicularly extending rearward from the top of the front wall 1222, and a bottom wall 1224 perpendicularly extending rearward from the bottom of the front wall 1222. The front wall 1222, the top wall 1223, and the bottom wall 1224 cooperatively form a receiving space 1225. Two fastening holes 1226 are defined in the front wall 1222, adjacent to the top wall 1223. A mounting panel 124 perpendicularly extends down from the rear side of the bottom wall 1224. Two long engaging holes 1244 are respectively defined in two sides of the mounting panel 124, adjacent to the bottom wall 1224 and extending from top to bottom. Four screw holes 1246 are defined in the mounting panel 124, between the engaging holes 1244. An L-shaped fixing portion 126 extends from the bottom of the mounting panel 124. The fixing portion 126 includes a rectangular supporting plate 1261 perpendicularly extending forward from the bottom of the mounting panel 124, and an extension plate 1263 perpendicularly extending down from the front side of the supporting plate 1261. Two guide holes 1242 are defined in a joint between the mounting panel 124 and the supporting plate 1261. A through hole 1262 is defined in the supporting plate 1261, between the guide holes 1242 and adjacent to the mounting panel 124. Two fastening holes 1264 are defined in the extension plate 1263. Two latching holes 1228 are defined in the rear side of the top wall 1223.

The engaging member 14 includes a rectangular sliding panel 142. Two L-shaped positioning portions 144 extend rearward from a top side of the sliding panel 142, respectively at two opposite ends of the sliding panel 142. Two L-shaped hooks 146 extend rearward from a bottom side of the sliding panel 142, respectively at the two opposite ends of the sliding panel 142. An operation block 147 extends down from the bottom side of the sliding panel 142, between the hooks 146. A guide surface 1468 is slantingly formed in a distal end of each hook 146. Four fastening holes 148 are defined in four corner of a front surface of the sliding panel 142.

The installing bracket 16 includes a rectangular front plate 164, two L-shaped side plates 166 extend from two opposite sides of the front plate 164. The front plate 164 and the side plates 166 cooperatively bound an installing space 162. Each side plate 166 includes a connecting plate 1661 perpendicularly extending rearward from the front plate 164, and an engaging plate 1662 perpendicularly extends out from a rear side of the connecting plate 1661. Two through holes 1664 are defined in each engaging plate 1662. Two positioning pieces 1644 extend in from a lower portion of the front plate 164. Each positioning piece 1644 defines a positioning hole 1646. Two elongated and parallel guide holes 1642 are defined in the front plate 164, between the positioning pieces 1644 and extending from top to bottom. Two L-shaped stopping plates 168 perpendicularly extend in from a bottom side of the front plate 164, respectively at two sides of the front plate 164. An opening 169 is formed between the stopping plates 168.

In the embodiment, each resilient member 17 is a spring, with two grommets 172 extending from two opposite ends of the spring.

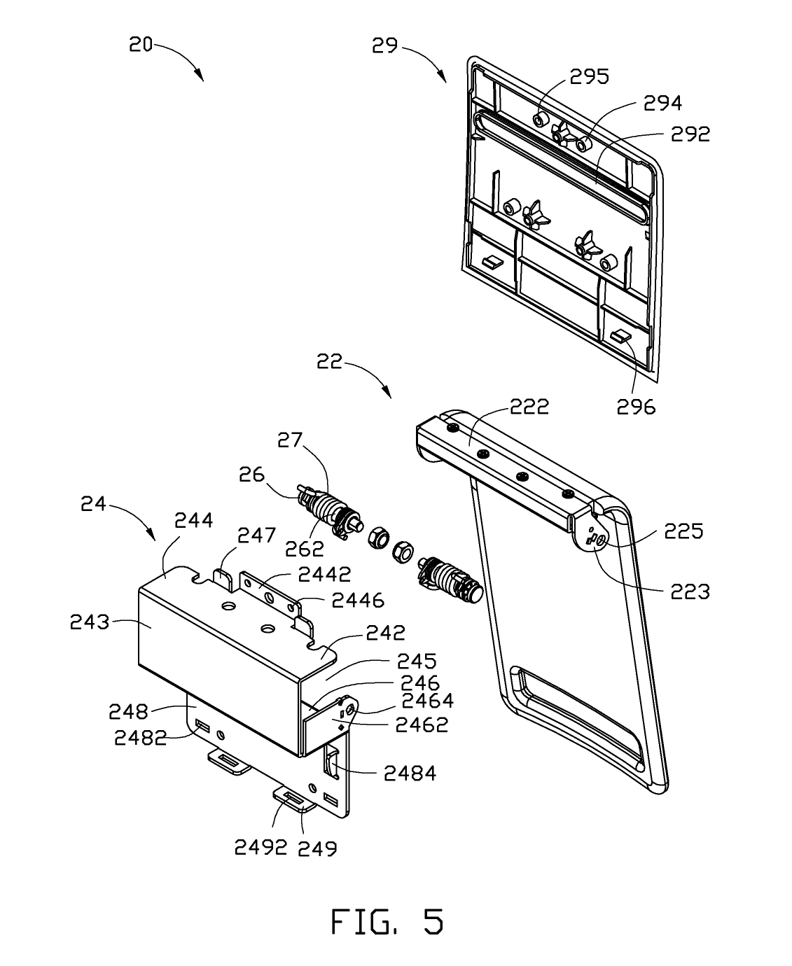

Referring to FIG. 5, the supporting apparatus 20 includes a supporting bracket 22, a connecting bracket 24, two shaft members 26, and a cover 29.

The supporting bracket 22 is substantially L-shaped, with a connecting portion 222 extending from a first end of the supporting bracket 22. Two pivoting plates 223 respectively extend from two opposite ends of the connecting portion 222. A shaft hole 225 is defined in each pivoting plate 223.

The connecting bracket 24 includes a substantially U-shaped receiving portion 242. The receiving portion 242 includes a rectangular front wall 243, a top wall 244 perpendicularly extending rearward from the top of the front wall 243, and a bottom wall 246 perpendicularly extending rearward from the bottom of the front wall 243. The front wall 243, the top wall 244, and the bottom wall 246 cooperatively bound a receiving space 245 for receiving the connecting portion 222 of the supporting bracket 22. A first fixing plate 2442 perpendicularly extends up from the middle of the rear side of the top wall 244, and defines two fixing holes 2446 therein. Two protrusions 247 protrude up from the rear side of the top wall 244, respectively at opposite ends of the first fixing plate 2442. A second fixing plate 248 perpendicularly extends down from the rear side of the bottom wall 246. Two latching holes 2482 are defined in a lower portion of the second fixing plate 248. Two engaging pieces 2484 perpendicularly extend forward from the second fixing plate 248, above the corresponding latching holes 2482, respectively. Two rectangular connecting pieces 249 perpendicularly extend forward from the bottom side of the second fixing plate 248, between the latching holes 2482. Each connecting piece 249 defines a connecting hole 2492 therein. Two connecting plates 2462 perpendicularly extend up from two opposite ends of the bottom wall 246, respectively. Each connecting plate 2462 defines a shaft hole 2464 therein.

The cover 29 is substantially rectangular, and defines a long opening 292 in the upper portion of the cover 29. Two columns 294 protrude forward from the front surface of the cover 29, above the opening 292. A screw hole 295 is axially defined in each column 294. Two hooks 296 extend forward from a lower portion of the cover 29, opposite to the corresponding latching holes 2482 of the connecting bracket 24, respectively.

Each shaft member 26 includes a shaft 262 and a torsion spring 27 fitting about the shaft 262.

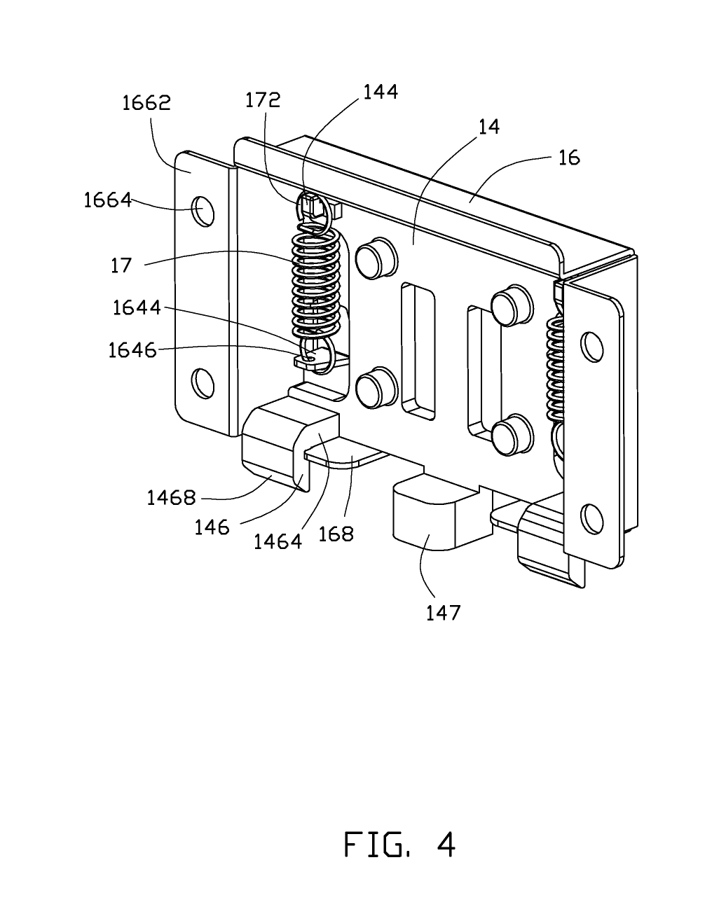

Referring to FIGS. 1-4, in assembly of the mounting apparatus 10, the engaging member 14 is received in the installing space 162 of the installing bracket 16. The sliding panel 142 is located between the positioning pieces 1644, and the hooks 146 abut against the corresponding stopping pieces 168, respectively. The operation block 147 is extended through the opening 169. The resilient members 17 are connected between the positioning pieces 1644 and the positioning portions 144. The grommets 172 of each resilient member 17 are respectively latched to the positioning hole 1646 and the corresponding positioning portion 144. Four screws 19 slidably extend through the guide holes 1642, to be screwed into the corresponding fastening holes 148. The engaging member 14 is then slidably mounted to the installing bracket 16, along the guide holes 1642. The resilient members 17 bias the hooks 146 to resist against the corresponding stopping pieces 168.

The installing bracket 16 is attached to the front surface of the mounting panel 124. The operation block 147 is inserted into the through hole 1262, and the hooks 146 are respectively inserted into the corresponding guide holes 1242. Four screws 18 extend through the through holes 1664, to be screwed into the screw holes 1246.

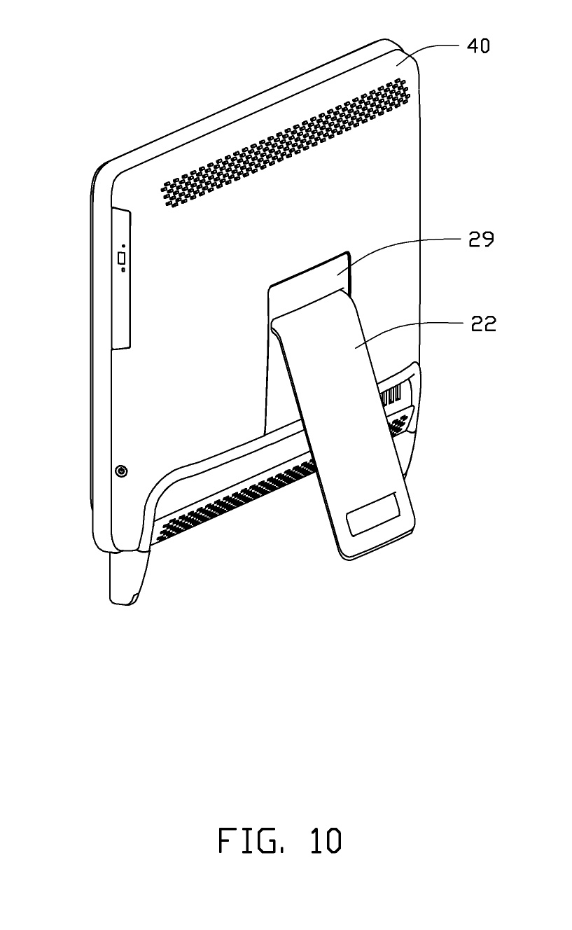

Referring to FIG. 1 and FIG. 10, in assembly of the mounting apparatus 10 to the main body 40, the front wall 1222 is received in the recess 42. Four screws are extended through the fastening holes 1226 and 1264, to be screwed into the corresponding screw holes 422. A bottom of the operation block 147 is exposed out of the main body 40 through the bottom of the recess 42.

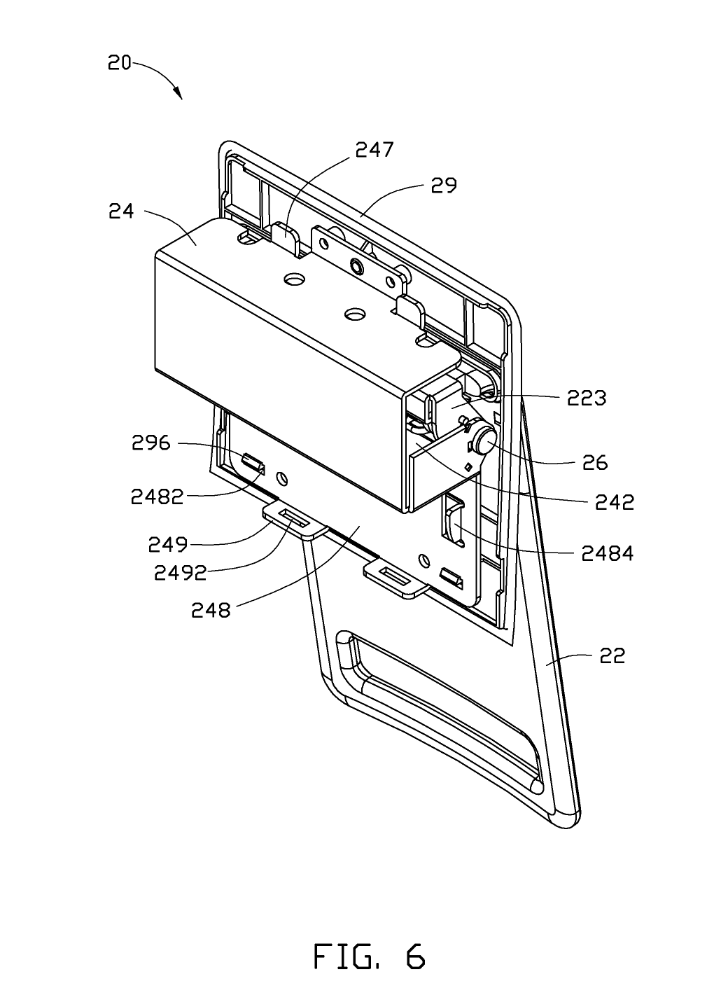

Referring to FIG. 5 and FIG. 6, in the assembly of the supporting apparatus 20, the connecting portion 222 is received in the receiving space 245 of the receiving portion 242 of the connecting bracket 24. The pivoting plates 223 are attached to the inner surfaces of the connecting plates 2462, respectively. The shafts 262 of the shaft members 26 pivotably extend through the shaft holes 2464 and 225. The two fingers of each torsion spring 27 resist against the corresponding connecting plate 2462 and the connecting portion 222, respectively. Therefore, the supporting bracket 22 is pivotably mounted to the connecting bracket 24. The second end of the supporting bracket 22 opposite to the connecting portion 222 extends through the opening 292 of the cover 29. Two screws extend through the fixing holes 2446, to be screwed into the screw holes 295 of the columns 294. The hooks 296 are latched into the corresponding latching holes 2482, therefore, the connecting bracket 24 is fixed to the front surface of the cover 29 to enclose the connecting portion 222.

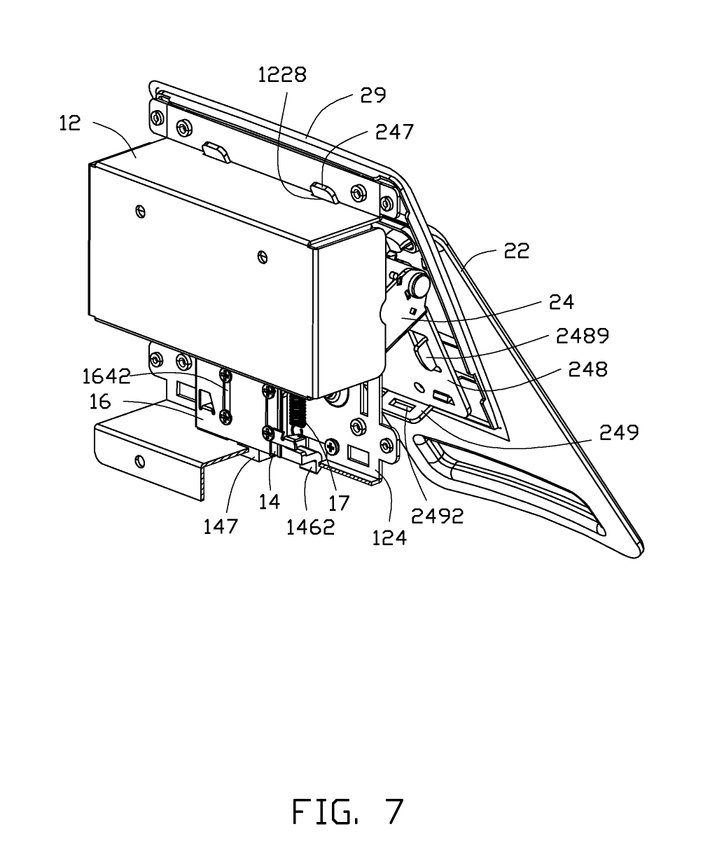

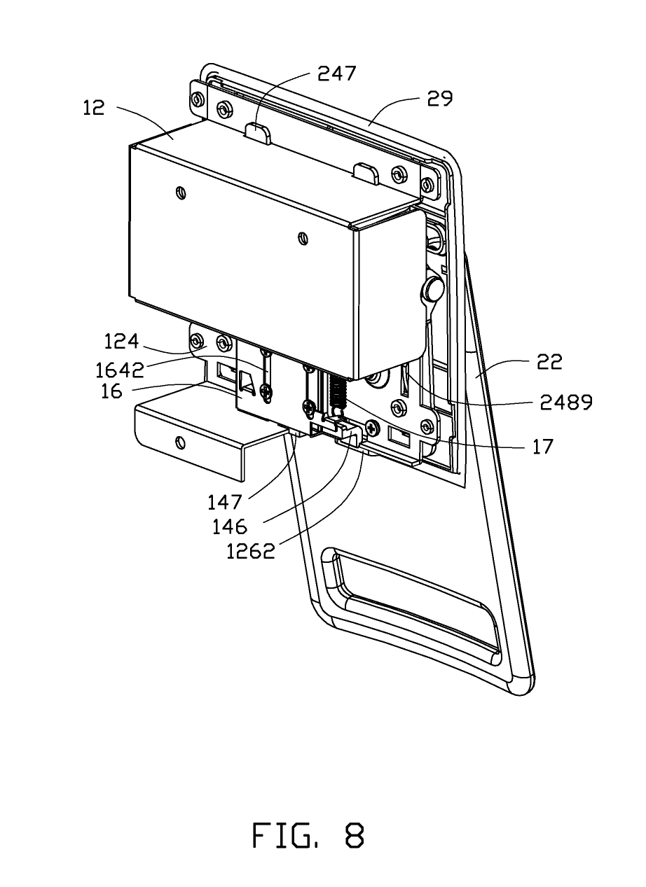

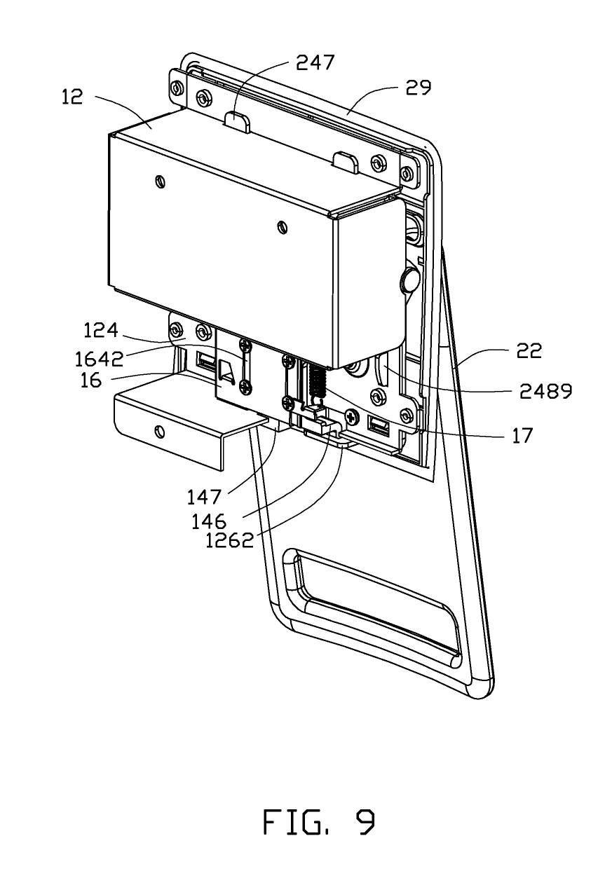

Referring to FIGS. 7-10, in the assembly of the supporting apparatus 20 to the mounting apparatus 10, the receiving portion 242 is received in the receiving space 1225. The protrusions 247 of the connecting bracket 24 are latched into the latching holes 1228 of the fixing bracket 12. The supporting apparatus 20 is pushed toward the mounting apparatus 10, the connecting pieces 249 abut against the guide surface 1468 of the corresponding hooks 146. The engaging member 14 is moved up away from the guide holes 1242 of the fixing bracket 12, to deform the resilient member 17. The connecting pieces 249 are moved under the corresponding guide holes 1242, until the connecting holes 2492 align with the corresponding hooks 146. The resilient members 17 are restored to bias the engaging member 14 to move down. The hooks 146 are extended through the corresponding guide holes 1242 and latched into the corresponding connecting holes 2492. The supporting apparatus 20 is then assembled to the main body 40 through the mounting apparatus 10 and the supporting bracket 22, thus supporting the main body 40.

When disassembling the supporting apparatus 20, the operation block 147 is pushed up to force the hooks 146 to disengage from the connecting holes 2492. The resilient member 16 is deformed. Thereby, the supporting apparatus 20 can be moved from the mounting apparatus 10. The main body 40 can still be hung on a wall with the fixing bracket 12.

Even though numerous characteristics and advantages of the embodiment(s) have been set forth in the foregoing description, together with details of the structures and functions of the embodiment(s), the disclosure is illustrative only, and changes may be made in detail, especially in matters of shape, size, and the arrangement of parts within the principles of the disclosure to the full extent indicated by the broad general meaning of the terms in which the appended claims are expressed.

What is claimed is:

1. An apparatus, comprising:
a mounting apparatus comprising a fixing bracket, and an engaging member slidably attached to the fixing bracket, wherein the fixing bracket defines a receiving space; and
a supporting apparatus comprising a connecting bracket and a supporting bracket mounted to the connecting bracket, wherein the connecting bracket comprises a receiving portion detachably received in the receiving space of the fixing bracket;
wherein a first engaging portion is formed on the engaging member, and a second engaging portion is formed on the connecting bracket, the engaging member is slidable between a first position where the first engaging portion engages with the second engaging portion and the supporting bracket executes the function of supporting, and a second position where the first engaging portion disengages from the second engaging portion.

2. The apparatus of claim 1, wherein the first engaging portion is a hook extending from the engaging member, the second engaging portion is a connecting piece extending from the connecting bracket and defining a connecting hole therein, the hook is operable to engage in or disengage from the connecting hole.

3. The apparatus of claim 2, wherein the fixing bracket comprises a frame, the frame comprises a rectangular first front wall, a first top wall extending rearward from a top side of the front wall, and a first bottom wall extending rearward from a bottom side of the first front wall, the first front wall, the first top wall, and the first bottom wall cooperatively bound the receiving space, a mounting panel extends down from a rear side of the first bottom wall, an installing bracket is fixed to the mounting panel, the engaging member is slidably mounted between the installing bracket and the mounting panel.

4. The apparatus of claim 3, wherein a sliding direction of the engaging member is up-to-bottom.

5. The apparatus of claim 3, wherein the engaging member comprises a sliding panel slidably attached to the installing bracket, the hook is substantially L-shaped, and extends rearward and down from the sliding panel, a fixing portion extends from the bottom of the mounting panel, opposite to the first bottom wall, a guide hole is defined in the fixing portion, the receiving portion comprises a second front wall, a second top wall extending rearward from a top side of the second front wall, and a second bottom wall extending rearward from a bottom side of the second front wall, a fixing plate extends down from a rear side of the second bottom wall, the connecting piece extends forward from a bottom side of the fixing plate, the hook extends through the guide hole, to engage in the connecting hole.

6. The apparatus of claim 3, further comprising a resilient member connected between the sliding panel and the installing bracket, to bias the sliding panel to make the hook engage in the connecting hole.

7. An electronic device, comprising:
a main body;
a mounting apparatus to hang the main body to a wall, the mounting apparatus comprising a fixing bracket mounted to the main body, an installing bracket fixed to the fixing bracket, and an engaging member slidably mounted to the installing bracket, wherein the fixing bracket defines a receiving space; and
a supporting apparatus comprising a connecting bracket, wherein the connecting bracket comprises a receiving portion detachably received in the receiving space of the fixing bracket, and a connecting piece;
wherein the connecting piece defines a connecting hole therein, the engaging member comprises a first hook inserted into the connecting hole to fix the supporting apparatus to the mounting apparatus, when disassembling the supporting apparatus, the engaging member is moved relative to the fixing bracket, the first hook is disengaged from the connecting hole.

8. The electronic device of claim 7, wherein the main body defines a first recess in a rear side of the main body, the fixing bracket comprises a frame, the frame comprises a rectangular first front wall, a first top wall extending rearward from a top side of the front wall, and a first bottom wall extending rearward from a bottom side of the first front wall, the first front wall, the first top wall, and the first bottom wall cooperatively bound the receiving space, a mounting panel extends down from a rear side of the first bottom wall, the installing bracket is fixed to the mounting panel, the engaging member is slidably mounted to the installing bracket along the direction of top-to-bottom.

9. The electronic device of claim 8, wherein the engaging member comprises a sliding panel slidably attached to the installing bracket, the first hook is substantially L-shaped, and extends rearward and down from the sliding panel, a fixing portion extends from the bottom of the mounting panel, opposite to the first bottom wall, a guide hole is defined in the fixing portion, the receiving portion comprises a second front wall, a second top wall extending rearward from a top side of the second front wall, and a second bottom wall extending rearward from a bottom side of the second front wall, a fixing plate extends down from a rear side of the second bottom wall, the connecting piece extends forward from a bottom side of the fixing plate, the first hook extends through the guide hole, to be inserted into the connecting hole.

10. The electronic device of claim 9, wherein a guide surface is slantingly formed on a distal end of the first hook for guiding the first hook to engage in the connecting hole.

11. The electronic device of claim 9, wherein two latching holes are defined in a rear side of the first top wall, two protrusions protrude up from a rear side of the second top wall, to engage in the latching holes.

12. The electronic device of claim 9, wherein four screw holes are defined in the mounting panel, the installing bracket comprises a rectangular front plate, two L-shaped side plates extend rearward from two opposite sides of the front plate, the front plate and the side plates cooperatively bound an installing space for receiving the engaging member, each side plate comprises a connecting plate extending from the front plate, and an engaging plate extending out from a rear side of the connecting plate, to be fixed on the mounting panel.

13. The electronic device of claim 12, wherein each engaging plate defines two through holes, four screws extend through the through holes, to screw in corresponding fastening holes defined in the mounting panel, thereby mounting the installing bracket to the fixing bracket.

14. The electronic device of claim 12, wherein two long engaging holes are defined in the mounting panel, two engaging pieces extend forward from the fixing plate of the connecting bracket, the engaging pieces are engaged into the corresponding engaging holes.

15. The electronic device of claim 12, wherein the mounting apparatus further comprises a resilient member, the resilient member comprises two grommets extending from two opposite ends, a positioning portion extends from a top side of the sliding panel, a positioning piece extends in from the front plate of the installing bracket, the resilient member is connected between the positioning piece and the position portion, to bias the engaging member toward the fixing portion of the fixing bracket.

16. The electronic device of claim 15, wherein two long slide slot are longitudinally defined in the front plate of the installing bracket, four fastener holes are defined in four corner of the sliding panel, four screws slidably extend through the slide slots, to be screwed into the corresponding fastening holes.

17. The electronic device of claim 9, wherein the fixing portion comprises a supporting plate extending forward from the bottom of the mounting panel, and an extension plate extending down from a front side of the supporting plate, the guide hole is defined in the joint between the mounting panel and the supporting plate, a through hole is defined in the supporting plate, an operation block extends down from the sliding panel, and extends through the through hole.

18. The electronic device of claim 9, wherein the supporting apparatus further comprises a cover fixed to the connecting bracket, two second hooks extend forward from a lower portion of the cover, two latching holes are defined in a lower portion of the fixing plate, the second hooks are latched into the corresponding latching holes.

19. The electronic device of claim 7, wherein the supporting apparatus further comprises a supporting bracket mounted to the receiving portion of the connecting bracket with a first end, to support the main body.

20. The electronic device of claim 19, wherein the supporting apparatus further comprises a cover fixed to the connecting bracket, a second end of the supporting bracket extends through the cover to be exposed.
